(19) United States
(12) Patent Application Publication
(10) Pub. No.: US 2026/0216652 A1
(43) Pub. Date: Jul. 30, 2026

(54) SYSTEMS AND METHODS FOR SEPARATING LITHIUM ISOTOPES FROM LITHIUM

(71) Applicant: Pure Lithium Corporation, Charlestown, MA (US)

(72) Inventors: Emilie BODOIN, Charlestown, MA (US); Donald R. SADOWAY, Charlestown, MA (US)

(21) Appl. No.: 19/319,339

(22) Filed: Sep. 4, 2025

Related U.S. Application Data
(60) Provisional application No. 63/691,949, filed on Sep. 6, 2024.

(51) Int. Cl. B01D 59/42; C22B 3/42; C22B 26/12; C23C 14/14; C23C 14/24; C23C 26/02

(52) U.S. Cl. CPC B01D 59/42; C22B 3/42; C22B 26/12; C23C 14/14; C23C 14/24; C23C 26/02

(57) ABSTRACT

In some aspects, the present disclosure provides a method of enriching lithium for lithium-6. In some embodiments, the method comprises providing an initial set of lithium atoms comprising lithium-6 atoms and lithium-7 atoms. In some embodiments, the method comprises migrating the initial set of lithium atoms from a first electrode towards a second electrode through a first polymer membrane to deposit a subset of lithium atoms from the initial set of lithium atoms onto the second electrode, wherein the lithium-6 concentration in the subset of lithium atoms is higher than the initial set of lithium atoms.

### CROSS-REFERENCE

This application claims the benefit of U.S. Provisional Application No. 63/691,949, filed Sep. 6, 2024, which is incorporated herein by reference in its entirety.

### BACKGROUND

Metal stable isotopes find uses in various engineering applications and scientific endeavors. Some metal stable isotopes (e.g., calcium, magnesium, iron, copper, and zinc) can be used as tracers in environmental or medical studies, and some can be used to produce other isotopes (e.g., lithium-6, which can be used to produce hydrogen-3, i.e., tritium).

### SUMMARY

In some aspects, the present disclosure provides a method of enriching lithium for lithium-6, comprising (a) providing an initial set of lithium atoms comprising lithium-6 atoms and lithium-7 atoms; (b) transporting the initial set of lithium atoms from a first electrode towards a second electrode through a first polymer membrane to deposit a subset of lithium atoms from the initial set of lithium atoms onto the second electrode, wherein the lithium-6 concentration in the subset of lithium atoms is higher than the initial set of lithium atoms, and wherein the first electrode and the second electrode are in electrical communication with each other; and (c) transporting the subset of lithium atoms from the second electrode towards a third electrode through a second polymer membrane to deposit a second subset of lithium atoms from the subset of lithium atoms onto the third electrode, wherein the lithium-6 concentration in the second subset of lithium atoms is higher than in the subset of lithium atoms, and wherein the second electrode and the third electrode are in electrical communication with each other.

In some embodiments, the second subset of lithium atoms comprises i) a lithium purity of at least 99.9 atomic percentage (at %) and (ii) a lithium-6 purity of at least 30 at % as measured by inductive coupled plasma.

In some embodiments, wherein the lithium purity is at least 99.91 at %, 99.92 at %, 99.93 at %, 99.94 at %, 99.95 at %, 99.96 at %, 99.97 at %, 99.98 at %, or 99.99 at %.

In some embodiments, wherein the lithium-6 purity is at least 40 at %, 50 at %, 60 at %, 70 at %, 80 at %, 90 at %, 91 at %, 92 at %, 93 at %, 94 at %, 95 at %, 96 at %, 97 at %, 98 at %, 99 at %, 99.1 at %, 99.2 at %, 99.3 at %, 99.4 at %, 99.5 at %, 99.6 at %, 99.7 at %, 99.8 at %, 99.9 at %, 99.91 at %, 99.92 at %, 99.93 at %, 99.94 at %, 99.95 at %, 99.96 at %, 99.97 at %, 99.98 at %, or 99.99 at %.

In some embodiments, wherein the second subset is deposited as metallic lithium.

In some embodiments, wherein the transporting the initial set of lithium atoms is under the fluence of electric current.

In some embodiments, wherein the transporting is ionically transporting through the electrolyte.

In some embodiments, wherein the transporting is caused by a power supply in an external circuit connected to the first electrode and the second electrode.

In some aspects, the present disclosure provides a composition comprising lithium having a lithium purity of at least 99.9 at % and a lithium-6 purity of at least 30 at %.

In some embodiments, the composition comprises a lithium purity of at least 99.91 at %, 99.92 at %, 99.93 at %, 99.94 at %, 99.95 at %, 99.96 at %, 99.97 at %, 99.98 at %, or 99.99 at %.

In some embodiments, the lithium-6 purity is at least 40 at %, 50 at %, 60 at %, 70 at %, 80 at %, 90 at %, 91 at %, 92 at %, 93 at %, 94 at %, 95 at %, 96 at %, 97 at %, 98 at %, 99 at %, 99.1 at %, 99.2 at %, 99.3 at %, 99.4 at %, 99.5 at %, 99.6 at %, 99.7 at %, 99.8 at %, 99.9 at %, 99.91 at %, 99.92 at %, 99.93 at %, 99.94 at %, 99.95 at %, 99.96 at %, 99.97 at %, 99.98 at %, or 99.99 at %.

In some aspects, the present disclosure provides a composition comprising lithium having a lithium purity of at least 99.9 at % and a lithium-7 purity of at least 95 at %.

In some embodiments, the composition comprises a lithium purity of at least 99.91 at %, 99.92 at %, 99.93 at %, 99.94 at %, 99.95 at %, 99.96 at %, 99.97 at %, 99.98 at %, or 99.99 at %.

In some embodiments, the lithium-7 purity is at least 96 at %, 97 at %, 98 at %, 99 at %, 99.1 at %, 99.2 at %, 99.3 at %, 99.4 at %, 99.5 at %, 99.6 at %, 99.7 at %, 99.8 at %, 99.9 at %, 99.91 at %, 99.92 at %, 99.93 at %, 99.94 at %, 99.95 at %, 99.96 at %, 99.97 at %, 99.98 at %, or 99.99 at %.

In some aspects, the present disclosure provides an electrode comprising a composition of the present disclosure.

In some embodiments, the metallic lithium comprises a total mass of at least 1, 2, 3, 4, 5, 6, 7, 8, 9, or 10 grams.

In some embodiments, the substrate comprises copper, nickel, aluminum, graphite coated copper, stainless steel, silicon, silver, an alloy, carbon (e.g., rough-surface carbon, graphene), a lithophilic material, gold, a copper alloy (Cu-Zn, Cu-Al, Cu-Sn), a metalized plastic foil, or any combination thereof.

In some aspects, the present disclosure provides an electrode comprising a composition of the present disclosure, wherein the composition is intercalated in the electrode.

In some aspects, the present disclosure provides a method of providing lithium, comprising heating an electrode of the present disclosure to melt or vaporize the lithium, and depositing the lithium on a second substrate.

In some aspects, the present disclosure provides a method of enriching lithium-6, comprising: (a) providing a first electrode, a second electrode, and an electrolyte between the first electrode and the second electrode, wherein the first electrode or the electrolyte comprises lithium atoms with a first lithium-6 purity; (b) applying a first electrical potential difference between the first electrode and the second electrode to transport the lithium atoms towards the second electrode and to deposit a first subset of the lithium atoms on the second electrode, wherein the first subset comprises a second lithium-6 purity that is higher than the first lithium-6 purity; (c) providing a third electrode and a second electrolyte between the second electrode and the third electrode; and (d) applying a second electrical potential difference between the second electrode and the third electrode to transport the first subset of the lithium atoms towards the third electrode and to deposit a second subset of the lithium atoms on the third electrode, wherein the second subset comprises a third lithium-6 purity that is higher than the second lithium-6 purity.

In some aspects, the present disclosure provides a method of enriching for an isotope of an element, comprising: (a) providing an initial composition comprising a first isotope of an element and a second isotope of the element; (b) transporting a first subset of atoms of the initial composition from a first position to a second position; and (c) migrating a second subset of atoms of the first subset from the second position to a third position to yield a final composition, wherein the final composition comprises a higher purity of the first isotope compared to the initial composition.

In some embodiments, the element is a transition metal.

In some embodiments, the transition metal is scandium, titanium, vanadium, chromium, manganese, iron, cobalt, nickel, copper, zinc, yttrium, zirconium, niobium, molybdenum, technetium, ruthenium, rhodium, palladium, silver, cadmium, lutetium, hafnium, tantalum, tungsten, rhenium, osmium, iridium, platinum, gold, mercury, lawrencium, rutherfordium, dubnium, seaborgium, bohrium, hassium, meitnerium, darmstadtium, roentgenium, or copernicium.

In some embodiments, the element is calcium, zinc, magnesium, sodium, potassium, boron, carbon, lead, rubidium, germanium, samarium, or strontium.

In some embodiments, the transporting the initial set of lithium atoms is under the fluence of electric current.

### INCORPORATION BY REFERENCE

All publications, patents, and patent applications mentioned in this specification are herein incorporated by reference to the same extent as if each individual publication, patent, or patent application was specifically and individually indicated to be incorporated by reference. To the extent publications and patents or patent applications incorporated by reference contradict the disclosure contained in the specification, the specification is intended to supersede and/or take precedence over any such contradictory material.

### BRIEF DESCRIPTION OF THE DRAWINGS

The novel features of the disclosure are set forth with particularity in the appended claims. A better understanding of the features and advantages of the present disclosure will be obtained by reference to the following detailed description that sets forth illustrative embodiments, in which the principles of the disclosure are utilized, and the accompanying drawings of which:

FIG. 1 shows a schematic of a method for enriching lithium-6, in accordance with some embodiments.

FIG. 2 shows a computer system, in accordance with some embodiments.

### DETAILED DESCRIPTION

Naturally occurring sources of lithium are often found comprising lithium-6 (⁶Li) and lithium-7 (⁷Li), the two stable isotopes of lithium. While different sources may have varying proportions of the two isotopes, lithium-7 usually found to be far more abundant. The natural abundance of lithium- 6 and lithium-7 is 7.59% and 92.41%, respectively. There are certain specialized uses of compositions comprising high purity of lithium-6 or lithium-7. The present disclosure, in some aspects, provides systems and methods for enriching for lithium-6 and/or lithium-7.

In some aspects, the present disclosure provides a method for enriching for lithium-6 in lithium. The method can comprise using electrodialysis to transport lithium-6 and lithium-7 ions from one electrode to another. As used herein, electrodialysis may refer to a process involving movement of one or more ions through a membrane using an applied electric field or potential difference. Because the lithium-6 has higher ionic mobility than lithium-7 (due to differences in mass and size), electrodialysis can enrich lithium-6 on the electrode that the lithium ions are migrating towards. Performing electrodialysis on an initial composition of lithium can enrich for lithium-6 so that the proportion of lithium-6 is higher than in the initial composition.

Electrodialysis can be performed on the enriched composition for a number of additional cycles, to further enrich lithium-6. Therefore, the method can be used to produce a composition having high lithium-6 purity. For example, the composition can comprise a lithium purity of at least 90, 91, 92, 93, 94, 95, 96, 97, 98, 99, 99.1, 99.2, 99.3, 99.4, 99.5, 99.6, 99.7, 99.8, or 99.9 atomic percent (at %) and a lithium-6 purity of at least 30 at %. In some embodiments, the composition can comprise a lithium purity of at most 91, 92, 93, 94, 95, 96, 97, 98, 99, 99.1, 99.2, 99.3, 99.4, 99.5, 99.6, 99.7, 99.8, 99.9, or 100 at %. As used herein, atomic percent can refer to the ratio between the number of atoms of one component to the total number of atoms of all components. The presence of a non-metallic element can be detected using, for example, inductively coupled plasma optical emission spectroscopy (ICP-OES) or X-ray microtomography. The presence of a non-metallic element may be detected using focused Ion Beam (FIB) with a secondary ion mass spectrometry (SIMS). The presence of a non-metallic element may be detected using electron energy loss spectroscopy (EELS), and/or transmission electron microscopy (TEM), by detecting and mapping lithium via the high ionization cross-section of the shallow Li K-edge that is 10-100 times greater than those of other light elements, e.g., O and F. Carbon, nitrogen, oxygen, sulfur, or fluorine can be measured by X-ray photoelectron spectroscopy (XPS), wavelength-dispersive X-ray spectroscopy (WDS), or energy dispersive spectroscopy (EDS).

Moreover, the electrodialysis can be performed to produce lithium of high purity (while also being enriched for either lithium-6 or lithium-7). Lithium can be extracted from a lithium resource using electrolytes that are configured to selectively conduct lithium while rejecting water and other metal ions (i.e., non-lithium ions) present in the lithium resource, so that high purity of lithium is extracted. Electrodialysis may also be performed using these electrolytes, which can subsequently purify lithium further and further with each additional stage of electrodialysis. By cascading 2 or more electrodialysis stages (e.g., at least 3, 4, 5, 6, 7, 8, 9, 10, 12, 14, 16, 18, 20, 30, or more), a composition having very high purity of lithium with a desired fraction of lithium-6 can be achieved. In some embodiments, enriched or depleted compositions may be recycled back into a stage to adjust output purity and to improve efficiency.

### Method

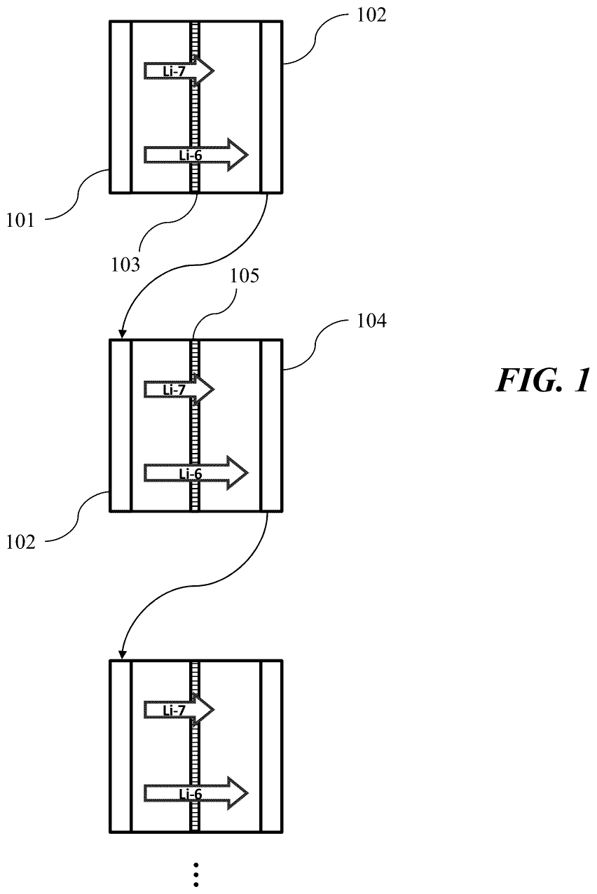

FIG. 1 shows a schematic of the method, in accordance with some embodiments. In some embodiments, the method comprises providing an initial composition comprising lithium-6 atoms and lithium-7 atoms. In some embodiments, the initial composition can be a lithium resource. In some embodiments, the lithium resource can be a natural resource, e.g., a geological resource comprising ore, minerals, or brine, or seawater.

In some embodiments, the method comprises migrating the lithium-6 atoms and the lithium-7 atoms from a first electrode towards a second electrode. The first electrode 101 and the second electrode 102 can be in electrical communication with each other. A subset of the lithium-6 atoms and a subset of the lithium-7 atoms can be deposited onto the second electrode. In some embodiments, the migration is through a first electrolyte. In some embodiments, the first electrolyte is a polymer membrane 103. In some embodiments, the migrating comprises applying an electric potential between the first electrode and the second electrode. In some embodiments, the electric potential can be at least 0.1, 0.2, 0.3, 0.4, 0.5, 0.6, 0.7, 0.8, 0.9, 1, 2, 3, 4, 5, 6, 7, 8, 9, or 10 V. In some embodiments, the electric potential can be at most 0.1, 0.2, 0.3, 0.4, 0.5, 0.6, 0.7, 0.8, 0.9, 1, 2, 3, 4, 5, 6, 7, 8, 9, or 10 V. In some embodiments, the lithium-6 concentration is higher in the subset than in the initial composition. In some embodiments, the method comprises breaking the electrical communication between the first electrode and the second electrode. In some embodiments, the method comprises breaking an electrical circuit comprising the first electrode and the second electrode.

In some embodiments, the method comprises migrating a subset of the lithium-6 atoms and the lithium-7 atoms from the second electrode towards a third electrode 104. A second subset of the lithium-6 atoms and a second subset of the lithium-7 atoms can be deposited onto the third electrode. The second electrode and the third electrode can be in electrical communication with each other. By cascading 2 or more electrodialysis stages (e.g., at least 3, 4, 5, 6, 7, 8, 9, 10, 12, 14, 16, 18, 20, 30, or more), a composition having very high purity of lithium with a desired fraction of lithium-6 can be achieved. With each additional stage, the lithium-6 purity of lithium that is deposited onto an electrode can be higher than the purity from a previous stage. In some embodiments, the migrating is through a second electrolyte. In some embodiments, the second electrolyte is a polymer membrane 105. The second electrolyte can be the same as the first electrolyte. The second electrolyte can be different from the first electrolyte. In some embodiments, the migrating comprises applying an electric potential between the second electrode and the third electrode. In some embodiments, the electric potential can be at least 0.1, 0.2, 0.3, 0.4, 0.5, 0.6, 0.7, 0.8, 0.9, 1, 2, 3, 4, 5, 6, 7, 8, 9, or 10 V. In some embodiments, the electric potential can be at most 0.1, 0.2, 0.3, 0.4, 0.5, 0.6, 0.7, 0.8, 0.9, 1, 2, 3, 4, 5, 6, 7, 8, 9, or 10 V. In some embodiments, the lithium-6 concentration in the second subset is higher than the subset. In some embodiments, the method comprises breaking the electrical communication between the second electrode and the third electrode. In some embodiments, the method comprises breaking an electrical circuit comprising the second electrode and the third electrode.

In some embodiments, the second subset is deposited as metallic lithium. For example, the second subset can be deposited on a substrate such as copper. The composition can be heated to melt or vaporize the lithium. The molten lithium or the vaporized lithium can be deposited on or be incorporated into another material for use. In some embodiments, the metallic lithium can comprise high lithium purity and lithium-6 purity or high lithium purity and lithium-7 purity. In some embodiments, the metallic lithium can comprise a mass of at least 1, 2, 3, 4, 5, 6, 7, 8, 9, or 10 grams. In some embodiments, the metallic lithium can comprise a mass of at most 1, 2, 3, 4, 5, 6, 7, 8, 9, or 10 grams. In some embodiments, the metallic lithium can comprise a mass of at least 1, 2, 3, 4, 5, 6, 7, 8, 9, 10, 20, 30, 40, 50, 60, 70, 80, 90, 100, 200, 300, 400, 500, 600, 700, 800, or 900 milligrams. In some embodiments, the metallic lithium can comprise a mass of at most 1, 2, 3, 4, 5, 6, 7, 8, 9, 10, 20, 30, 40, 50, 60, 70, 80, 90, 100, 200, 300, 400, 500, 600, 700, 800, or 900 milligrams. In some embodiments, the second subset is intercalated into an electrode.

In some aspects, the present disclosure provides a method of purifying an isotope of an element. In some embodiments, the method comprises providing an initial composition comprising a first isotope of an element and a second isotope of the element. In some embodiments, the method comprises migrating a first subset of the first isotope and the second isotope from a first position to a second position. In some embodiments, the method comprises migrating a second subset of the first subset of the first isotope and the second isotope from the second position to a third position to yield a final composition, wherein the final composition comprises a higher purity of the first isotope compared to the initial composition.

In some embodiments, the element is a transition metal. In some embodiments, the element is calcium, zinc, magnesium, sodium, potassium, boron, carbon, lead, rubidium, germanium, samarium, or strontium. In some embodiments, the transition metal is scandium, titanium, vanadium, chromium, manganese, iron, cobalt, nickel, copper, zinc, yttrium, zirconium, niobium, molybdenum, technetium, ruthenium, rhodium, palladium, silver, cadmium, lutetium, hafnium, tantalum, tungsten, rhenium, osmium, iridium, platinum, gold, mercury, lawrencium, rutherfordium, dubnium, seaborgium, bohrium, hassium, meitnerium, darmstadtium, roentgenium, or copernicium.

### Composition

In some embodiments, the lithium purity is at least 99.91 at %, 99.92 at %, 99.93 at %, 99.94 at %, 99.95 at %, 99.96 at %, 99.97 at %, 99.98 at %, or 99.99 at %. In some embodiments, the lithium purity is at most 99.91 at %, 99.92 at %, 99.93 at %, 99.94 at %, 99.95 at %, 99.96 at %, 99.97 at %, 99.98 at %, or 99.99 at %. In some embodiments, the lithium-6 purity is at least 40 at %, 50 at %, 60 at %, 70 at %, 80 at %, 90 at %, 91 at %, 92 at %, 93 at %, 94 at %, 95 at %, 96 at %, 97 at %, 98 at %, 99 at %, 99.1 at %, 99.2 at %, 99.3 at %, 99.4 at %, 99.5 at %, 99.6 at %, 99.7 at %, 99.8 at %, 99.9 at %, 99.91 at %, 99.92 at %, 99.93 at %, 99.94 at %, 99.95 at %, 99.96 at %, 99.97 at %, 99.98 at %, or 99.99 at %. In some embodiments, the lithium-6 purity is at most 40 at %, 50 at %, 60 at %, 70 at %, 80 at %, 90 at %, 91 at %, 92 at %, 93 at %, 94 at %, 95 at %, 96 at %, 97 at %, 98 at %, 99 at %, 99.1 at %, 99.2 at %, 99.3 at %, 99.4 at %, 99.5 at %, 99.6 at %, 99.7 at %, 99.8 at %, 99.9 at %, 99.91 at %, 99.92 at %, 99.93 at %, 99.94 at %, 99.95 at %, 99.96 at %, 99.97 at %, 99.98 at %, or 99.99 at %. In some embodiments, the lithium7 purity is at least 96 at %, 97 at %, 98 at %, 99 at %, 99.1 at %, 99.2 at %, 99.3 at %, 99.4 at %, 99.5 at %, 99.6 at %, 99.7 at %, 99.8 at %, 99.9 at %, 99.91 at %, 99.92 at %, 99.93 at %, 99.94 at %, 99.95 at %, 99.96 at %, 99.97 at %, 99.98 at %, or 99.99 at %. In some embodiments, the lithium-7 purity is at most 96 at %, 97 at %, 98 at %, 99 at %, 99.1 at %, 99.2 at %, 99.3 at %, 99.4 at %, 99.5 at %, 99.6 at %, 99.7 at %, 99.8 at %, 99.9 at %, 99.91 at %, 99.92 at %, 99.93 at %, 99.94 at %, 99.95 at %, 99.96 at %, 99.97 at %, 99.98 at %, or 99.99 at %. The purity can be measured by inductive coupled plasma.

In some embodiments, the composition comprises less than 1500 ppm of a trace metal. In some embodiments, the composition comprises less than 1400, 1300, 1200, 1100, 1000, 900, 800, 700, 600, 500, 400, 300, 200, 100, 90, 80, 70, 60, 50, 40, 30, 20, 10, 9, 8, 7, 6, 5, 4, 3, 2, 1, 0.9, 0.8, 0.7, 0.6, 0.5, 0.4, 0.3, 0.2, or 0.1 ppm of a trace metal. In some embodiments, the ppm can be by mass or by count. In some embodiments, the composition comprises more than 0, 1, 2, 3, 4, 5, 6, 7, 8, 9, 10, 20, 30, 40, 50, 60, 70, 80, 90, 100, 200, 300, 400, 500, 600, 700, 800, 900, 1000, 2000, 3000, 4000, or 5000 parts-per-billion (ppb) of a trace metal. In some embodiments, the ppb can be by mass or by count. In some embodiments, the ppb can correspond to a basis used for the instrument to detect the trace element. In some embodiments, the trace metal can be aluminum, barium, calcium, chromium, iron, iridium, magnesium, tungsten, zinc, cobalt, or sodium. In some embodiments, a trace element may form an alloy with lithium. In some embodiments, the composition comprises less than 12, 11, 10, 9, 8, 7, 6, 5, 4, 3, 2, 1, 0.9, 0.8, 0.7, 0.6, 0.5, 0.4, 0.3, 0.2, or 0.1 ppm of aluminum. In some embodiments, the composition comprises less than 15, 14, 13, 12, 11, 10, 9, 8, 7, 6, 5, 4, 3, 2, 1, 0.9, 0.8, 0.7, 0.6, 0.5, 0.4, 0.3, 0.2, or 0.1 ppm of barium. In some embodiments, the composition comprises less than 45, 40, 35, 30, 25, 20, 15, 10, 9, 8, 7, 6, 5, 4, 3, 2, 1, 0.9, 0.8, 0.7, 0.6, 0.5, 0.4, 0.3, 0.2, or 0.1 ppm of calcium. In some embodiments, the composition comprises less than 1, 0.9, 0.8, 0.7, 0.6, 0.5, 0.4, 0.3, 0.2, or 0.1 ppm of chromium. In some embodiments, the composition comprises less than 2, 1, 0.9, 0.8, 0.7, 0.6, 0.5, 0.4, 0.3, 0.2, or 0.1 ppm of iron. In some embodiments, the composition comprises less than 13, 12, 11, 10, 9, 8, 7, 6, 5, 4, 3, 2, 1, 0.9, 0.8, 0.7, 0.6, 0.5, 0.4, 0.3, 0.2, or 0.1 ppm of iridium. In some embodiments, the composition comprises less than 1000, 900, 800, 700, 600, 500, 400, 300, 200, 100, 90, 80, 70, 60, 5,0 40, 30, 20, 10, 9, 8, 7, 6, 5, 4, 3, 2, or 1 ppm of magnesium. In some embodiments, the composition comprises less than 23, 20, 15, 10, 9, 8, 7, 6, 5, 4, 3, 2, 1, 0.9, 0.8, 0.7, 0.6, 0.5, 0.4, 0.3, 0.2, or 0.1 ppm of tungsten. In some embodiments, the composition comprises less than 0.7, 0.6, 0.5, 0.4, 0.3, 0.2, or 0.1 ppm of zinc. In some embodiments, the composition comprises less than 45, 40, 35, 30, 25, 20, 15, 10, 9, 8, 7, 6, 5, 4, 3, 2, 1, 0.9, 0.8, 0.7, 0.6, 0.5, 0.4, 0.3, 0.2, or 0.1 ppm of sodium. In some embodiments, the composition comprises less than 45, 40, 35, 30, 25, 20, 15, 10, 9, 8, 7, 6, 5, 4, 3, 2, 1, 0.9, 0.8, 0.7, 0.6, 0.5, 0.4, 0.3, 0.2, or 0.1 ppm of cobalt.

### Electrolyte

In some embodiments, an electrolyte comprises a polymer, a ceramic, a coordination compound, or any combination thereof. In some embodiments, an electrolyte comprises a polymer doped or functionalized with coordination compounds, wherein the coordination compounds are configured to conduct lithium ions. Any number and any combination of electrolytes disclosed herein may be employed. For example, a method or system of the present disclosure may use 1, 2, 3, 4, 5, or more electrolytes in combination. The electrolytes may be integrated into a unitary film, e.g., having multiple solid state electrolytes adhered to one another. The electrolytes may be interposed, e.g., two nearest solid state electrolytes may be interposed by a liquid electrolyte.

In some embodiments, an electrolyte comprises a lithium conductive membrane comprising a polymer. In some embodiments, the polymer is doped or functionalized with a coordination compound. The coordination compound can be configured to coordinate selectively with lithium ions. The polymer (with or without the coordination compound) can be a hydrophobic polymer. Certain hydrophobic polymer may also be non-conductive, or otherwise have conductivity insufficient to be able to effectively transport lithium ions across a membrane made out of the polymer. By adding coordination compounds to the polymer, the polymer may be made to be able to prevent the passage of water while also conducting lithium ions. The coordination compound can comprise any coordination compound disclosed herein.

In some embodiments, the lithium conductive membrane is configured to provide a Li⁺ conductivity of at least about 1.0 ×10⁻⁶ S/cm at room temperature through the lithium conductive membrane. In some embodiments, the Li⁺ conductivity is at least 2, 3, 4, 5, 6, 7, 8, 9, 10, 20, 30, 40, 50, 60, 70, 80, 90, or 100 ×10⁻⁶ S/cm at room temperature through the lithium conductive membrane. In some embodiments, the Li⁺conductivity is less than 2, 3, 4, 5, 6, 7, 8, 9, 10, 20, 30, 40, 50, 60, 70, 80, 90, or 100×10⁻⁶ S/cm at room temperature through the lithium conductive membrane.

In some embodiments, the polymer can be a copolymer. For example, the polymer can be an alternating, random, graft, or block copolymer. In some embodiments, the polymer can comprise a hydrophobic repeating unit. The hydrophobic repeating unit can comprise an acrylate monomer selected from the group consisting of methyl acrylate, ethyl acrylate, propyl acrylate, butyl acrylate, lauryl acrylate, and any combination thereof. The hydrophobic repeating unit can comprise a methacrylate monomer selected from the group consisting of methyl methacrylate, ethyl methacrylate, butyl methacrylate, lauryl methacrylate, and any combination thereof. The hydrophobic repeating unit can comprise a siloxane monomer selected from the group consisting of dimethyl siloxane, diethyl methoxy siloxane, and any combination thereof. The hydrophobic repeating unit can comprise a fluoroalkyl monomer selected from the group consisting of a perfluoroalkyl monomer, a partially fluorinated monomer, octafluoropentyl acrylate, octafluoropentyl methacrylate, and any combination thereof. The hydrophobic repeating unit can comprise an anionic monomer selected from the group consisting of —(CF₂)ₘ—SO₂—N—-SO₂—(CF₂)n—CF₃ (m=0-5, n=0-5),—(CF₂)m-—SO₂—N—SO₂—(CHF₂)ₙ—CHF₂,—(CF₂)m—SO₂-N—SO2—(CF2)n—CH₂F, —COO—,—SO₃—,-cyano(trifluoromethanesulfonyl)imide,-2-trifluoromethyl-4,5-dicyanoimidazolide, and any combination thereof. The anionic monomer can be present in a ratio of about 1:1 with the coordination compound. The anionic monomer can be present in a ratio of at least 0.1, 0.2, 0.3, 0.4, 0.5, 0.6, 0.7, 0.8, 0.9, 1, 2, 3, 4, 5, 6, 7, 8, 9, or 10 to 1 with the coordination compound. The anionic monomer can be present in a ratio of at most 0.1, 0.2, 0.3, 0.4, 0.5, 0.6, 0.7, 0.8, 0.9, 1, 2, 3, 4, 5, 6, 7, 8, 9, or 10 to 1 with the coordination compound.

In some embodiments, the polymer comprises an additive configured to increase the Li⁺conductivity. In some embodiments, the additive is hydrophilic. In some embodiments, the additive is hydrophobic. In some embodiments, the additive comprises polyethylene glycol methacrylate. In some embodiments, the polymer comprises a cross-linker.

The polymer can be functionalized with the coordination compound in an amount sufficient to provide a percolating network of lithium ion conductive paths in the lithium conductive membrane. The amount sufficient to provide the percolating network may be determined by measuring lithium conductivity as a function of concentration of the coordination compound; the slope of conductivity versus concentration may be greater above the percolation concentration compared to below the percolation concentration.

In some embodiments, the coordination compound can be functionalized to the polymer. The functionalization may be via a vinyl, aldehyde, allylic, acrylate, amine, azide, alkyne, alkene, thiol functional groups, or any other suitable functional group. In some embodiments, the coordination compound can be doped in the polymer without functionalization. The coordination compound can comprise a crown ether, a cryptand, or any other coordination compound disclosed herein.

### Lithium Resource

In some aspects, the present disclosure provides systems and methods of extracting lithium from a lithium resource. A lithium resource can be a natural resource, e.g., a geological resource comprising ore, minerals, or brine, or seawater.

In some embodiments, the lithium resource comprises an aqueous solution of metal salts comprising (i) a lithium salt and (ii) a sodium salt, a magnesium salt, a calcium salt, a potassium salt, or any combination thereof. In some embodiments, the lithium resource comprises an aqueous salt solution. In some embodiments, the lithium resource comprises sodium, potassium, magnesium, calcium, boron, chlorine, SO₄²⁻, nitrogen, an alkali metal, an alkali earth metal, or any combination thereof. In some embodiments, the magnesium salt comprises MgCl₂. In some embodiments, the sodium salt comprises NaCl. In some embodiments, the lithium resource comprises LiCl, Li₂SO₄, or both.

In some embodiments, a ratio of magnesium to lithium in the lithium resource is at least 0, 1, 2, 3, 4, 5, 6, 7, 8, 9, 10, 20, 30, 40, 50, 60, 70, 80, 90, 100, 200, 300, 400, 500, 600, 700, 800, 900, or 1000 on a molar basis. In some embodiments, a ratio of magnesium to lithium in the lithium resource is at most 1, 2, 3, 4, 5, 6, 7, 8, 9, 10, 20, 30, 40, 50, 60, 70, 80, 90, 100, 200, 300, 400, 500, 600, 700, 800, 900, or 1000 on a molar basis. In some embodiments, a ratio of magnesium to lithium in the lithium resource is at least 0, 1, 2, 3, 4, 5, 6, 7, 8, 9, 10, 20, 30, 40, 50, 60, 70, 80, 90, 100, 200, 300, 400, 500, 600, 700, 800, 900, or 1000 on a mass basis. In some embodiments, a ratio of magnesium to lithium in the lithium resource is at most 1, 2, 3, 4, 5, 6, 7, 8, 9, 10, 20, 30, 40, 50, 60, 70, 80, 90, 100, 200, 300, 400, 500, 600, 700, 800, 900, or 1000 on a mass basis.

In some embodiments, the lithium resource is pretreated to remove a metal cation. In some embodiments, the metal cation comprises magnesium, calcium, sodium, potassium, iron, or any combination thereof. In some embodiments, the metal cation is removed by adsorption, extraction, absorption, electrodialysis, precipitation, nanofiltration, solvent extraction, or any combination thereof. In some embodiments, the adsorption or the extraction comprises binding the metal cation to a coordination compound. In some embodiments, the absorption is performed by contacting the lithium resource with lithium-manganese oxide, titanium oxide, aluminum hydroxide, iron phosphate, clay minerals, zeolite, zirconium phosphate, tin antimonate, antimony oxide, tantalum oxide, niobium oxide, or any combination thereof.

In some embodiments, lithium can be extracted from a geological resource, such as clay and/or ore. In some embodiments, the geological resource can comprise a lithium mineral (e.g., LiAlSi₂O₆). The geological resource can be treated with sulfuric acid to obtain solution comprising Li₂SO₄. The Li₂SO₄ can be crystallized or further treated with a base to obtain LiOH (e.g., by adding Ca(OH)₂) or Li₂CO₃ (e.g., by adding Na₂CO₃). In some embodiments, CaSO₄ can be added to the geological resource. In some embodiments, the geological resource can be baked at high temperature. In some embodiments, LiSO₄ can be extracted using water to obtain an aqueous solution. In some embodiments, the aqueous solution can be concentrated to obtain Li₂SO₄ as a crystal.

In some embodiments, the lithium source or the electrolyte comprises an additive, wherein the additive is configured to bind with lithium ions in the lithium source preferentially over the lithium ions binding with water. In some embodiments, the lithium source comprises an anion with a chemical structure of (RS(O)₂)₂N⁻, where R is a substituent selected from the group of alkyl, perfluorinated alkyl, partially fluorinated alkyl, aryl, perfluorinated aryl, partially fluorinated aryl, and combinations thereof.

### Substrate

The substrate can comprise copper, nickel, aluminum, graphite coated copper, stainless steel, silicon, silver, an alloy, carbon (e.g., rough-surface carbon, graphene), a lithophilic material, gold, a copper alloy (Cu-Zn, Cu-Al, Cu-Sn), a metalized plastic foil, or any combination thereof. The substrate can be a current collector. The substrate can have a roughness of less than 0.1, 0.2, 0.3, 0.4, 0.5, 0.6, 0.7, 0.8, 0.9, 1, 2, 3, 4, 5, 6, 7, 8, 9, 10, 20, 30, 40, 50, 60, 70, 80, 90, or 100 μm. The substrate can have a roughness of greater than 0.1, 0.2, 0.3, 0.4, 0.5, 0.6, 0.7, 0.8, 0.9, 1, 2, 3, 4, 5, 6, 7, 8, 9, 10, 20, 30, 40, 50, 60, 70, 80, 90, or 100 μm. The substrate can have a roughness of less than 1 μm. The substrate can have a roughness of <2 μm.

The substrate can be electropolished. The substrate can be etched. The substrate can be acid etched. The substrate can comprise a coat. The coating can comprise Si, Zn, ZnO, Al2O3, or other alloys. The coat can be created using sputtering, spin coating, or electrodepositing. The coat can be configured to lower a nucleation energy barrier of lithium deposition. The coat can be electrically conductive. The coat can provide higher nucleation efficiency than an uncoated substrate material. The coat can provide a higher density of nucleation sites than an uncoated substrate material. The coat can provide more uniform nucleation than an uncoated substrate material. The coat can comprise a roughness of at least 10, 50, or 100 nm. The coating can have a thickness of at least 10, 20, 30, 40, 50, 60, 70, 80, 90, 100, 150, 200, 300, 400, or 500 nm. The coating can have a thickness of at most 10, 20, 30, 40, 50, 60, 70, 80, 90, 100, 150, 200, 300, 400, or 500 nm. The coating can have a thickness of 50-200 nm.

### Computing System

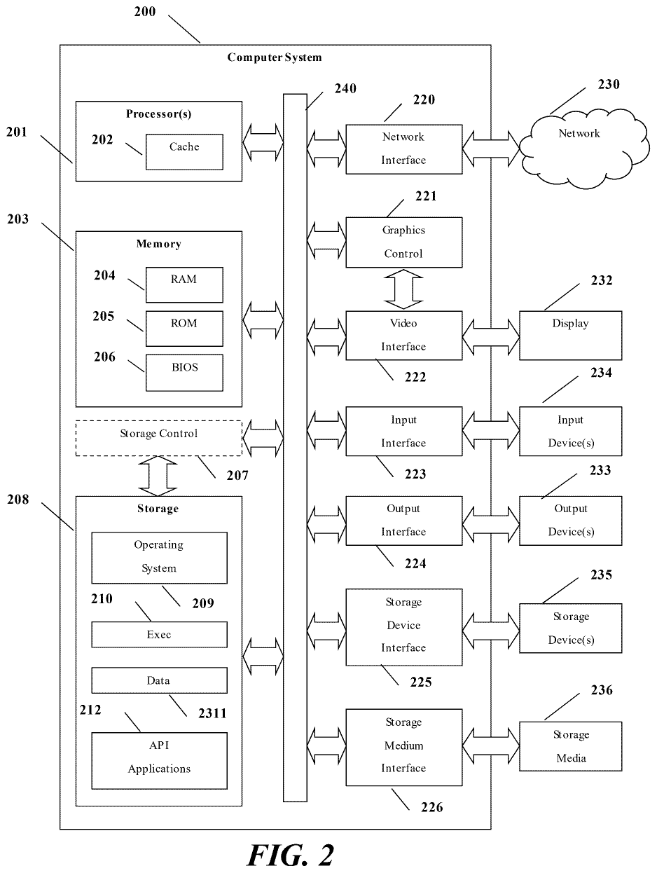

In some aspects, the present disclosure describes a computer-implemented system comprising: a digital processing device comprising: at least one processor, an operating system configured to perform executable instructions, a memory, and a computer program including instructions executable by the digital processing device to enrich an isotope such as lithium-6 using a method or a system disclosed herein. In some aspects, the present disclosure describes a computer-implemented method, implementing any one of the methods disclosed herein in a computer system. Referring to FIG. 2, a block diagram is shown depicting an exemplary machine that includes a computer system 200 (e.g., a processing or computing system) within which a set of instructions can execute for causing a device to perform or execute any one or more of the aspects and/or methodologies for enriching an isotope such as lithium-6 using a method or a system disclosed herein. The components in FIG. 2 are examples only and do not limit the scope of use or functionality of any hardware, software, embedded logic component, or a combination of two or more such components implementing particular embodiments.

Computer system 200 may include one or more processors 201, a memory 203, and a storage 208 that communicate with each other, and with other components, via a bus 240. The bus 240 may also link a display 232, one or more input devices 233 (which may, for example, include a keypad, a keyboard, a mouse, a stylus, etc.), one or more output devices 234, one or more storage devices 235, and various tangible storage media 236. All of these elements may interface directly or via one or more interfaces or adaptors to the bus 240. For instance, the various tangible storage media 236 can interface with the bus 240 via storage medium interface 226. Computer system 200 may have any suitable physical form, including but not limited to one or more integrated circuits (ICs), printed circuit boards (PCBs), mobile handheld devices (such as mobile telephones or PDAs), laptop or notebook computers, distributed computer systems, computing grids, or servers.

While preferred embodiments of the present disclosure have been shown and described herein, it will be obvious to those skilled in the art that such embodiments are provided by way of example only. Numerous variations, changes, and substitutions will now occur to those skilled in the art without departing from the disclosure. It should be understood that various alternatives to the embodiments of the present disclosure may be employed in practicing the present disclosure. It is intended that the following claims define the scope of the present disclosure and that methods and structures within the scope of these claims and their equivalents be covered thereby.

1. A method of enriching lithium for lithium-6, comprising:
(a) providing an initial set of lithium atoms comprising lithium-6 atoms and lithium-7 atoms;
(b) transporting the initial set of lithium atoms from a first electrode towards a second electrode through a first polymer membrane to deposit a subset of lithium atoms from the initial set of lithium atoms onto the second electrode, wherein the lithium-6 concentration in the subset of lithium atoms is higher than the initial set of lithium atoms, and wherein the first electrode and the second electrode are in electrical communication with each other; and
(c) transporting the subset of lithium atoms from the second electrode towards a third electrode through a second polymer membrane to deposit a second subset of lithium atoms from the subset of lithium atoms onto the third electrode, wherein the lithium-6 concentration in the second subset of lithium atoms is higher than in the subset of lithium atoms, and wherein the second electrode and the third electrode are in electrical communication with each other.

2. The method of claim 1, wherein the second subset of lithium atoms comprises i) a lithium purity of at least 99.9 atomic percentage (at %) and (ii) a lithium-6 purity of at least 30 at % as measured by inductive coupled plasma.

3. The method of claim 2, wherein the lithium purity is at least 99 at %.

4. The method of claim 2 wherein the lithium- 6 purity is at least 40 at %.

5. The method of claim 1, wherein the second subset of lithium atoms is electrodeposited as metallic lithium on the third electrode.

6. The method of claim 1, wherein the transporting the initial set of lithium atoms is under the fluence of electric current.

7. The method of claim 6, wherein the first polymer membrane is an electrolyte, and wherein the transporting in (b) is ionically transporting through the electrolyte.

8. The method of claim 1, wherein the transporting in (b) is caused by a power supply in an external circuit connected to the first electrode and the second electrode.

9.-18. (canceled)

19. A-The method of claim 7, further comprising heating the third electrode to melt or vaporize the lithium metal to generate molten lithium or lithium vapor, and depositing the molten lithium or the lithium vapor on a substrate.

20.-25. (canceled)

26. The method of claim 4, wherein the lithium- 6 purity is at least 90 at %.

27. The method of claim 26, wherein the lithium- 6 purity is at least 96 at %.

28. The method of claim 27, wherein the lithium- 6 purity is at least 99 at %.

29. The method of claim 28, wherein the lithium- 6 purity is at least 99.9 at %.

30. The method of claim 29, wherein the lithium purity is at least 99.99 at %.

31. The method of claim 5, wherein the metallic lithium comprises less than 45 ppm of sodium.

32. The method of claim 31, wherein the metallic lithium comprises less than 1000 ppm of magnesium.

33. The method of claim 31, wherein the metallic lithium comprises less than 45 ppm of calcium.

34. The method of claim 1, wherein the subset of lithium atoms is electrodeposited as metallic lithium on the second electrode.

35. The method of claim 19, wherein the heating the third electrode comprises melting the lithium metal, and wherein the depositing comprises depositing the molten lithium on the substrate.

36. The method of claim 19, wherein the heating the third electrode comprises vaporizing the lithium metal, and wherein the depositing comprises depositing the lithium vapor on the substrate.
